(19) United States
(12) Patent Application Publication
(10) Pub. No.: US 2005/0029515 A1
(43) Pub. Date: Feb. 10, 2005

(54) Organic/inorganic oxide mixed film, passive device contained electronic substrate using the film, and method of manufacturing organic/inorganic oxide mixed film

(75) Inventors: Akira Nagai, Hitachi (JP); Toshiyuki Ohno, Hitachi (JP); Fusao Hojo, Naka (JP); Shinji Yamada, Tsukuba (JP); Mikio Konno, Sendal (JP); Yomokazu Tanase, Sendai (JP); Daisuke Naga, Sendai (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(73) Assignee: Hitachi, Ltd., Tokyo (JP)

(21) Appl. No.: 10/912,108

(22) Filed: Aug. 6, 2004

(30) Foreign Application Priority Data
Aug. 7, 2003 (JP) 2003-206488

(51) Int. Cl. H01L 35/24

(52) U.S. Cl. 257/40

(57) ABSTRACT

An organic/inorganic oxide mixture has high capacitance density so as to realize a capacitor material that can be self-contained in a substrate. The mixture film made of inorganic oxide particle has a mean particle size of less than 90 nm dispersed in organic polymer, of which relative dielectric constant is more than 10 and thickness is less than 900 nm.

### CLAIM OF PRIORITY

The present application claims priority from Japanese application serial no. 2003-206488, filed on Aug. 7, 2003, the content of which is hereby incorporated by reference into this application.

### BACKGROUND OF THE INVENTION

The present invention relates to organic/inorganic oxide mixed film having high dielectric constant, a passive device contained electronic substrate using the film, a method of manufacturing organic/inorganic oxide mixed film, and a method of manufacturing a passive device contained electronic substrate. The organic/inorganic oxide mixed film is particularly useful as material for forming capacitor and is characteristic of high capacitance density.

As electronic appliances have been required of high performance and compact size these days, needs for higher density, higher performance and higher function of package circuit board have become stronger. Accordingly, in order to improve the packaging efficiency in mounting electronic components on a package circuit board, there arises a need for a substrate that self-contains passive devices including inductor (L), capacitor (C) and resistor (R) (which is called LCR as a whole).

While signals used therein have become faster in speed, higher in capacity and lesser in power consumption, generation of nose has become a problem. To resolve it, there has been proposed an idea that capacitors and related parts, which used to be mounted near semiconductor devices, are formed inside the substrate. With this construction, discrete chip for the capacitor is no longer needed to be mounted on the surface of the substrate, and hence dense packaging becomes available. In addition, distance between semiconductor devices and capacitors can be shorter, and hence electric characteristic can improve and also effect of noise can be reduced drastically. Furthermore, since the number of parts and number of connections decrease, reliability can be expected to improve.

A technique of integrating the passive devices in a substrate for the purpose of allowing of dense packaging and reducing noise has been known for long as a method of baking ceramic substrate together with LCR at a time. Of late, there has been another active attempt to integrate LCR in a resin substrate.

For example, as a method of forming a dielectric layer of capacitor, it has been examined to make a substrate using resin material in which filler having high dielectric constant is dispersed. As a method of forming a resistor on a resin substrate, it has been examined to print with resistance paste using carbon black. In addition, as a method of forming an inductor on a resin substrate, it has been examined to form a coil shape by patterning a conductor circuit.

Furthermore, in order to realize high-accuracy LCR on a circuit board, a sequential laminating technique with the aid of a semiconductor process using laser irradiation or the like has been examined these years.

The above conventional methods of integrating LCR in a substrate involve the following problems. Baking ceramic substrate together with LCR at a time involves a problem of productivity and forming a large substrate is costly. In addition, because of high baking temperature, it is not suitable for integrating passive devices such as semiconductor devices at the same time. The sequential laminating technique with the aid of a semiconductor process also involves a problem of productivity and is costly. Also because of high temperature of the process, it is not suitable for integrating passive devices such as semiconductor devices at the same time.

On the contrary, the method of making a substrate using resin material in which filler having high dielectric constant does not involve any of the above problems. The existing resin material, however, generally involves a problem in improving dielectric constant characteristic. That is, increasing the filler content to improve the dielectric constant results in brittleness of the material, and so the substrate is easy to deform, crack or chip when it is made thin. As a material of which dielectric constant is improved by increasing the filler content, there has been disclosed an epoxy resin material to which PMNPT (lead magnesium niobate/lead titanate) and barium titanate are added by 85 vol. % to achieve the dielectric constant of 150 as shown in ECTC (Electronic Components and Technology Conference), Lecture Draft Collection, 2001, Vol. 51, pp. 1408. Because of very high filler content, however, it is concerned that the material is very brittle.

Materials commercially available at present and considered applicable to integration in a substrate generally have low filler content of around 60 vol. % and relative dielectric constant of around 40 as shown in Development of “capacitor film” allowing dense packaging on a printed wiring board” (http//www.mew.co.jp/press/0112/0112-2.htm)

Even with this material, since the particle size of the filler used in it is large, sufficient thickness needs to be ensured to achieve satisfactory insulation characteristic, and so capacitor portion is generally formed in a film thickness of more than 10 μm. Accordingly, the capacitance density is very low like 50 pF/mm² at the maximum.

Japanese laid-open patent publication 2003-26932 (Abstract and claims) offers ultra-fine particle mixed resin particle and compounds and electronic devices containing the particle. The document describes that the thickness of the film (dielectric substance) is less than 50 μm but normally more than 1 μm, and the thickness disclosed therein is more than 2 μm in reality. It also describes a mixture of inorganic ultra-fine particle and resin coating has a particle size of 0.1 to 5 μm.

The thickness of the dielectric substance shown in Table 1 and Table 2 of the Patent Document 2003-26932 is 2 to 10 μm, from which the capacitance density, most important characteristic among all is found to be 31.0 to 212.5 pF/mm².

### SUMMARY OF THE INVENTION

In order to solve the above problems, the present invention has paid an attention to the inorganic oxide to be dispersed in the resin and found out that sufficient characteristic needed for capacitor material can be realized even in a thin condition if the mean particle size is controlled. Consequently, the present invention can improve the capacitance density of capacitor and thereby offer a passive device contained electronic substances or electronic devices containing high-performance capacitor material.

The present invention offers the following means for solving the above problems. One of the means is an organic/inorganic oxide mixed film made of practically spherical inorganic oxide particle, having a mean particle size of less than 90 nm, dispersed in organic polymer, of which relative dielectric constant is more than 10 and thickness is less than 900 nm.

In the above means, the inorganic oxide shall preferably be practically spherical and the spherical inorganic oxide that can be realized by a manufacturing method according to an embodiment to be described later is preferable. However small the particle size may be, use of the oxide like this enables to prevent cohesion when it is mixed with organic polymer material. In addition, use of the method of dispersing oxide particle in organic polymer as recommended in this invention enables to prevent cohesion of particles further surely.

In this invention, the inorganic oxide cannot only be a single metallic oxide but also be other types of oxides including mixture of two different oxides, compound oxide like barium titanate, and oxide having a perovskite structure.

The important feature of the present invention is that inorganic oxide particle having a small particle size is dispersed in organic polymer so as to form very thin film having a high dielectric constant and accordingly capacitor having high dielectric constant and capacitance density can be formed. According to the present invention, use of the method in the embodiments to be described later enables to form a compound film of organic polymer and inorganic oxide that is far thinner than conventional one. Nevertheless, the present invention is not limited to those embodiments.

According to this invention, because the mean particle size of the oxide particle is very small and also because cohesion of the particles is prevented, a very thin compound dielectric film can be formed and accordingly the unevenness in the thickness of the above mixture film can be made less than 50 nm. Thus, capacitor having less varied capacitance can be offered.

The unevenness in the thickness of the film is measured as follows. A probe type surface profile measuring device (Model DEKTAK-3 manufactured by ULVAC, Inc., formerly Japan Vacuum Technology Co., Ltd.) is used to measure the film thickness. In the measurement, part of the film is peeled off by a cutter and height is measured at the peeled off portion, where the difference between the mean highest and mean lowest is defined as the mean film thickness. In addition, the difference between the maximum unevenness and minimum unevenness at the highest is defined as the unevenness in the thickness of the film.

Use of filler in a range less than 90 nm of inorganic oxide to be contained in the organic film enables to form a well-dispersed film. Particle of 10 to 80 nm is particularly preferable.

Increasing the volume percentage of the inorganic oxide to be contained in the organic film to more than 15 vol. % particularly to more than 20 vol. % enables to form a film having high dielectric constant. However, if the volume percentage exceeds 70 vol. %, ease of forming the film and soundness of the film may possibly be lost.

In addition, use of fluorine-containing polymer or epoxy compound as the organic substance produces the following advantages. Fluorine-containing polymer is highly heat resistive and so it makes matrix resin having a high dielectric constant. Epoxy resin provides excellent moldability and so a passive device contained electronic substrate or electronic device can easily be formed through a conventional substrate manufacturing process.

Use of barium titanate as the inorganic oxide enables to realize capacitor material having a high dielectric-constant characteristic.

Because the film thickness is made thinner, the capacitance density as capacitor can be increased to more than 1 nF/mm² and so a passive device contained electronic substrate or electronic device containing a capacitor with high density and high capacity can be realized.

Another means of the present invention is a passive device contained electronic substrate self-containing a capacitor made of organic/inorganic oxide mixture, in which the relative dielectric constant of the organic film containing inorganic oxide having a mean particle size of less than 90 nm is more than 10 and thickness is less than 900 nm. Since the capacitor of the present invention has very high capacitance density, a high-performance substrate can be made in a compact size. Accordingly, wiring length can be shorter, lower inductance can be realized, electrical characteristic can be improved, and effect of noise and electromagnetic wave can be reduced. Having capacitor parts self-contained in the substrate enables to decrease laying cables on the substrate and consequently the number of layers in a multi-layer substrate can be lessened and so cost reduction can be expected. Since having the parts self-contained decreases the number of parts and number of connections, reliability can be expected to improve.

The present invention offers a method of manufacturing organic/inorganic oxide mixed film, in which practically spherical inorganic oxide particle, having a mean particle size of less than 90 nm, is dispersed in organic solvent, the dispersed solution is mixed with organic polymer and dispersed in the organic polymer, and the mixture is then applied on the substrate surface of an electronic device board or electronic component and dried and/or hardened to form mixed film of which thickness is less than 900 nm. In this method, it is preferable that the inorganic oxide particle is prepared by a sol/gel method.

The characteristic of the present invention is further described hereunder in detail. Resin compound made of resin in which ceramic powder having a relatively high dielectric constant is dispersed is suitable as material for forming capacitor inside a package circuit board because it allows to form a capacitor layer at a relatively low temperature. The capacitor layer is formed generally at a process temperature of 150 to 250° C. although it depends upon the softening temperature and hardening temperature of the resin.

Next, a general method of the present invention is described concretely hereunder. To start with, how to produce inorganic oxide to be contained in the resin is described. Dissolve metallic material in alcohol and allow them to react completely to generate metal alkoxide. Since metallic material is generally stored in oil, it may be necessary to wash it with hexane before putting into alcohol. Then, mix multiple alkoxides prepared as above and homogenize the mixture by a circulation process. This circulation shall be processed in a nitrogen flow. Then, while stirring the mixed and homogenized alkoxide solution, add water as initiator and perform hydrolyzation and condensation polymerization (sol/gel reaction). Heat may be applied to accelerate the reaction. After the reaction is complete, remove excessive solvent and byproduct using a centrifuge so as to prevent cohesion and sintering caused by drying, and then, for a preservation purpose, disperse the produced fine-particle inorganic oxide again in a solvent that can be mixed with matrix inorganic substance.

Alcohol used above includes methanol, ethanol, propanol and butanol but is not limited thereto so far as it reacts with metallic material used above to generate alkoxide. Metallic material includes Ba, Sr, Ca, La, Ti, Ta, Zr, Cu, Fe, W, Co, Mg, Zn, Ni, Nb, Pb, Li, K, Sn, Al and Sm but is not limited thereto so far as it is an oxide used as capacitor material. In addition, it is possible to use two or more of the above together. In the sol/gel reaction, use of the three metals, Ba, Sr and Ti out of the above is particularly preferable as the capacitor material. In addition, use of magnetic nano-particle using ferrite such as Fe oxide enables to for coils, and installing the coils inside the substrate enables to realize various functions including filtering function.

In generating alkoxide, it is possible to mix not only alcohol but also nonpolar solvent. Since the mixed nonpolar solvent makes the hydroxy group of alcohol unstable, and accordingly is apt to restrain nucleus generation reaction and accelerate nucleus growth reaction, it provides the process with a function of increasing the particle size of the fine particle to be produced or widening the particle size distribution. Accordingly, adding nonpolar solvent as needed is effective to control the particle size and particle size distribution. The nonpolar solvent as above includes toluene, xylene and cyclohexane but is not limited thereto so far as the solvent gives effect on the hydroxy group.

Although material to be selected as the solvent that can be mixed with matrix organic substance (organic polymer) is different depending upon the matrix organic substance to be used, a solvent that can dissolve the matrix organic substance is generally employed in most cases. For example, it can be acetone, methanol, methyl ethyl ketone, methyl isobutyl ketone, dimethyl formamide, dimethyl acetamide, N-methyl pyrrolidone, cyclohexanone, toluene, xylene, dimethyl sulfoxide and diethylene glycol monomethyl ether but not limited thereto. Furthermore, two or more can be used together as mixed solvent.

Next, general preparation of the organic/inorganic oxide mixed solvent is described hereunder. To mix the solution preserving the produced fine-particle inorganic oxide with the matrix organic substance to begin with, several different methods are available. One is simply to add the matrix organic substance to the preserving solution, and then stirred to cause dispersion. In this process, using heat or ultrasonic wave is effective to accelerate the dispersion. Another is to process the solution preserving the produced fine-particle inorganic oxide in a centrifuge to remove excessive solvent and obtain the fine-particle inorganic oxide in the form of slurry in wet condition. The slurry is then mixed and dispersed in the matrix organic substance solution. Also in this process, using heat or ultrasonic wave as needed is effective.

There is no limitation to the matrix organic substance used above so far as it can form an insulation layer. For example, it includes epoxy resin, phenol resin, maleimide resin, polyimide, polyamide, polyamide imide, fluorine-containing resin and silicone resin. If light sensitivity can be added to the matrix resin, patterning becomes available on the substrate to be produced, which is advantageous for dense packaging because capacitors can be formed at any portion of the substrate.

The biggest difference from the conventional organic matrix capacitor material containing filler is that the present invention is very thin and applicable in a thickness of less than 900 nm. This thickness can be easily realized by applying fine-particle inorganic oxide using the sol/gel reaction as explained in this invention.

The fine particle obtained from the sol/gel reaction is in a range from 1 nm to 200 nm approximately, which can be produced with high controllability if appropriate conditions are selected. In addition, the obtained particle is nearly spherical and well dispersible in organic polymer, and the characteristic of the film to be produced from it is uniform. It is found that, by controlling the mean particle size of the obtained fine particle to less than 90 nm when dispersed in the organic substance, the product has excellent characteristic as capacitor material even if it is made in a thickness of less than 900 nm. The object of the present invention can be achieved if the mean particle size of the fine particle to be mixed in the organic polymer is less than 90 nm, but use of the fine particle having a mean particle size preferably ranging from 10 to 80 nm is effective. Fine particles less than 10 nm are apt to cohere with each other in the process of dispersing them into the organic polymer and so they are not preferred as the resultant mean particle size may sometimes exceed 90 nm.

It is a characteristic of the present invention to use spherical filler. Since this filler having a high dielectric constant does not have any edge, it is effective to lessen the concentration of magnetic field. Accordingly, the dielectric strength of the product increases and so a capacitor having a characteristic of more than 20 kV/mm (20 V/μm) can be easily realized.

In the present invention, use of a suitable coupling agent enables to increase the adhesion between the inorganic oxide ultra-fine particle and resin matrix. Applicable coupling agent includes silane coupling agent, titanate type coupling agent and aluminum chelate type coupling agent. Silane coupling agent includes amino silane, methacrylate silane, vinyl silane and phenyl amino silane but is not limited thereto so far as it can disperse the filler of the present invention in the matrix resin.

Typical method of applying the coupling agent is separated into two ways: one is to subject the inorganic oxide (filler) and inorganic substrate (glass fiber substrate) to surface treatment in advance and the other is to add the coupling agent to the resin compound. When adding the agent to the resin compound, about 0.01 to 5 wt. % of the compound is preferable. In particular, about 0.05 to 0.5 wt. % is preferable.

Since the organic/inorganic oxide mixture, which is organic matrix material of the invention, can be bonded with conductive metal very strongly, capacitor material generally having the peel strength of more than 1 kN/m can be realized easily. In addition, since it has high insulation resistance, capacitor material of more than 1 GΩ can also be realized.

Capacitor using the organic/inorganic oxide mixture realized by the present invention can be used as devices having various functions and formed on a substrate, including decoupling capacitor, filter, duplexer, noise filter, band pass filter, low pass filter, common mode filter, normal mode filter, and bypass capacitor. Since decoupling capacitor is particularly required to have high capacity in many cases, high capacitance density of the mixture is very much advantageous. In case a capacitor having low capacity is needed, the area of the product is reduced or the amount of added fine particle is decreased so as to use the product as a film having high mechanical characteristic.

With a substrate that self-contains the capacitors using the organic/inorganic oxide mixture realized by the invention, the number of passive devices mounted on the surface can be less and so a larger number of active devices can be mounted. According, the substrate can be used in an electronic appliance of extremely high performance. In addition, since the number of components to be mounted can be less, fewer circuits are needed on the substrate, and so reduction of the number of layers and size of the substrate can be realized. It is very much effective also for cost reduction.

Since the matrix of the capacitor of this invention uses organic material, it is advantageous, compared to conventional inorganic matrix material, that a low temperature process can be employed in integrating the capacitor in the substrate. For example, a sheet bonded with conductor metal on two sides or on one side can be formed in a process lower than 250° C. The conductor metal can generally be copper, copper alloy, ferroalloy, nickel alloy, silver, silver alloy, gold or gold alloy. For a process of forming an insulation layer, which functions as capacitor, on the conductor metal, spin coating or screen printing can be applied for example. This film can be formed thicker more easily than in using inorganic matrix material, and a film of 0.5 to 1 μm can be formed in one process.

The electronic appliance that uses a substrate self-containing the capacitor made of the organic/inorganic oxide mixture realized by the present invention can realize extremely compact size and high performance, and is very much effective for cost reduction. Because of its low loss characteristic (tanδ is less than 1%), it can be used in combination with inductor in a high frequency electronic appliances. Because of its high capacitance (more than 1 nF/mm²) and common mode filter characteristic (combination of twist pair coil and magnetic material), it is applicable to high-speed module related appliances. In addition, memory capacitor making the best of the high capacitance (more than 1 nF/mm²) is effective to reduce the refresh cycles of sheet display.

### BRIEF DESCRIPTION OF THE DRAWINGS

FIG. 1 is a flowchart showing the manufacturing method of the mixed film of the present invention;

FIG. 2 is a flowchart showing the manufacturing process of the multi-layer electronic substrate self-containing the capacitor of the present invention; and

FIG. 3 is a cross-sectional view showing the construction of the multi-layer electronic substrate self-containing the capacitor of the present invention.

### DETAILED DESCRIPTION OF THE PREFERRED EMBODIMENTS OF THE INVENTION

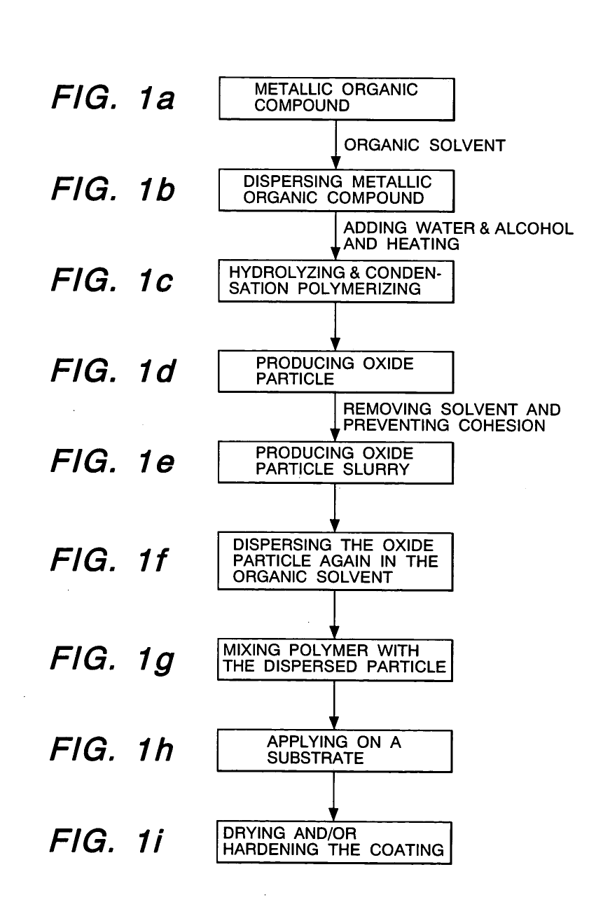

Next, typical embodiments of the present invention are described hereunder. The scope of the invention, however, is not limited to those embodiments. Prior to the description of each embodiment, the manufacturing process of the mixed film of the present invention is described, using FIG. 1. FIG. 1 is a flowchart explaining the embodiments of the invention, and the present invention is in now way limited to the flowchart.

To begin with, prepare metallic element powder or organic compound thereof (a). In case of metallic element, react it with alcohol and produce alkoxide. Disperse the material in the mixed solvent of alcohol and non-water type solvent (b), and then add water and alcohol to the solvent and, while stirring and heating as needed, perform hydrolyzation and condensation polymerization (c). As a result, fine particle having a mean particle size of less than 90 nm dispersed in the water/organic solvent is produced (d).

Next, remove excessive solvent from this dispersed product by a centrifuge (e). This prevents cohesion of the fine particle. Then, disperse the fine particle in organic solvent again (f), mix with organic polymer and mix thoroughly (g). Apply this compound on the surface of a substrate by an application method such as spin coating (h), and dry and/or harden it to produce required mixture film (i).

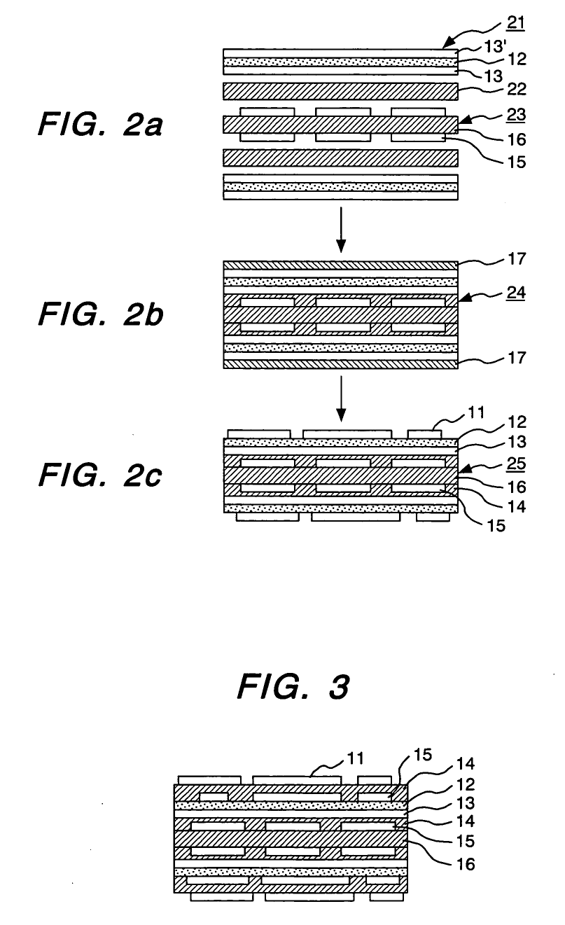

FIG. 2 shows the manufacturing process of a passive device contained electronic substrate according to an embodiment of the present invention. On an organic/inorganic oxide mixture film (dielectric substance) 12 of the present invention formed on a conductor foil 13, another conductor foil 13′ is bonded to make a capacitor forming lamination 21. This lamination, bonding layer 22, and inner substrate insulation layer 16, on both sides of which inner substrate conductor 15 patterned as specified is attached, are laminated as shown in FIG. 2(a), and then compressed and heated for integration. Thus, a six-layer substrate 24 ready for patterning on the outside is produced as shown in FIG. 2(b). In this process, the bonding layer is fluidized and flows between the conductor patterns to for a bonding layer 14. Next, a resist film 17 is formed on each outer conductor 13 and 13′. necessary resist pattern is formed on it by photo lithography, and desired outer conductor pattern 11 is formed by etching to produce a passive device contained electronic substrate 25 as shown in FIG. 2(c).

FIG. 3 is a cross-sectional view of a passive device contained electronic substrate according to another embodiment, wherein the same symbol represents the same component as in FIG. 2. In FIG. 3, in addition to the inner substrate insulation layer 16, an outer substrate insulation layer 18 is formed outside the organic/inorganic oxide mixed film 13 of the present invention. Each component is laminated as shown in FIG. 3 in the same manner as in FIG. 2, and then they are compressed, heated and hardened to produce a passive device contained electronic substrate. The embodiment in FIG. 2 is so constructed that part of the organic/inorganic oxide mixed film 13 is exposed out of the conductor (which does not mean that the compound film is actually open to the air but that it is located further outside than in FIG. 3). The passive device contained electronic substrate of the present invention includes this construction and that in FIG. 3.

### Embodiment 1

### Preparation of Inorganic Oxide Particle

0.025 mol of tetraethoxy titanium is added to 250 ml of ethanol/toluene co-solvent, and the solution is circulated for 24 hours under nitrogen ambient for a homogenization purpose. Then, while stirring the obtained alkoxide solution, 250 ml of water/ethanol mixed initiator solution, of which water density is so adjusted that the water density of the whole solution becomes 20 mol/l, is added and hydrolyzation and condensation polymerization are performed. Reaction temperature is 70° C. and reaction time is 5 hours. After the reaction is complete, the product is removed of solvent by a centrifuge so as to prevent cohesion of the particles and then dispersed again in NMP (N-methyl pyrrolidone), and thus dispersed titanium oxide particle is obtained.

### Preparation of Organic/Inorganic Mixed Solution

Polyamide imide NMP solution is added to the NMP solution in which the titanium oxide has been dispersed, and the mixture is stirred for 24 hours at 60° C. for thorough mixing.

### Production of Capacitor Film for Evaluation and Measurement of Dielectric Constant

The above mixed solution is applied on a silicone substrate having Pt/Ti electrodes by spin coating, and the substrate is burned for 10 minutes at 350° C. so as to remove the solvent and produce a dielectric film. In addition, gold electrodes are deposited on the surface to measure the dielectric constant.

### Embodiment 2

### Preparation of Inorganic Oxide Particle

Under nitrogen ambient, 0.060 mol of metal barium is put in 200 g of ethanol and stirred for 30 minutes to produce barium alkoxide. After ensuring that barium has been completely dissolved, 220 g of toluene and 0.060 mol of tetraethoxy titanium is added and the mixture is subjected to a circulation process for 24 hours to produce compound alkoxide. Then, the obtained alkoxide is added into a solution of 360 g of water and 110 g of ethanol, and stirred for 24 hours at 70° C. to produce barium titanate particle. The obtained particle is removed of reaction solvent by a centrifuge, and then preserved by the solvent substitution with 2-methoxy ethanol so as to prevent cohesion of the particles.

Preparation of organic/inorganic mixed solution, production of capacitor film for evaluation, and measurement of dielectric constant are the same as in Embodiment 1.

### Embodiment 3

Barium titanate particle is produced and evaluated in the same manner as in Embodiment 2 except that octanol is used instead of ethanol, and the product is evaluated in the same manner as in Embodiment 2.

### Embodiment 4

### Preparation of Inorganic Oxide Particle

Under nitrogen ambient, 0.006 mol of metal barium and 0.006 mol of metal strontium are put in a mixture of 50 ml of toluene and 50 ml of ethanol and the mixture is subjected to a circulation process for 60 minutes at 70° C. to produce barium/strontium alkoxide. After ensuring that barium and strontium have been completely dissolved, 0.012 mol of tetraethoxy titanium is added and the mixture is subjected to a circulation process for 24 hours at 70° C. to produce compound alkoxide. Then, the obtained alkoxide is added into a solution of 72 g of water and 80 ml of ethanol, and the mixture is subjected to a circulation process for 5 hours at 70° C. to produce strontium/barium titanate particle. The obtained particle is removed of reaction solvent by a centrifuge, and then the solvent is substituted with 2-methoxy ethanol for preservation so as to prevent cohesion of the particles.

Preparation of organic/inorganic mixed solution, production of capacitor film for evaluation, and measurement of dielectric constant are the same as in Embodiment 1.

### Embodiment 5

Organic/inorganic oxide mixed solution is prepared and evaluated in the same manner as in Embodiment 2 except that polyvinylidene fluoride is used instead of polyamide imide.

### Embodiment 6

Organic/inorganic oxide mixed solution is prepared and evaluated in the same manner as in Embodiment 4 except that epoxy resin compound is used instead of polyamide imide. The epoxy resin compound used therein is a material comprising bisphenol A diglycydil ether compound, phenol novolak compound and imidazole (2-ethyl-4-methy imidazole).

### Embodiments 7 & 8

The mount of added inorganic oxide and thickness of dielectric substance are varied in the same manner as in Embodiment 5 and the dielectric constant is evaluated. Table 1 shows the result of the evaluation. According to Table 1, the dielectric film of the present invention is very thin and so the capacitance density is as excellent as 140 pF/mm² at the minimum and 1,330 pF/mm² at the maximum.

### Embodiment 9

Using the capacitor material obtained in Embodiment 6, a passive device contained electronic substrate shown in FIG. 3 is produced. Instead of producing a silicone substrate having Pt/Ti electrodes, a dielectric film is formed between two copper foils of 18 μm thick and the double copper-foiled lamination is placed on each side of a two-layer substrate to produce a 6-layer substrate. FIG. 2 shows a brief manufacturing process. Capacitors having a surface electrode of 1×1 mm square (1 mm²) to 10×10 mm (100 mm²) are formed and evaluated. Thus, capacitors having a characteristic of 0.6 to 60 nF can be integrated in the substrate.

### Comparative Sample 1

Commercially available barium titanate (having a mean particle size of 600 nm, manufactured by Fuji Titanium Co., Ltd.) is added to polyvinylidene fluoride by 60 vol. % to produce a dielectric film. The result shows that a thickness of 20 μm is necessary to achieve the dielectric strength of 20 kV/mm. The capacitance is 7 pF/mm².

TABLE 1
Result of Dielectric Characteristic Evaluation

| | | Mean | | | | | | | |
|---|---|---|---|---|---|---|---|---|---|
| | | particle | | | Relative | | | Capacitance | Dielectric |
| | Metallic | size | | | dielectric | Thickness | Unevenness | density | strength |
| | oxide | (nm) | Vol. % | Organic | constant | (μm) | (nm) | (pF/mm²) | (20 kV/mm) |
| Embodiment 1 | Titanium | 5 | 15 | Polyamide | 12 | 0.5 | 100 | 210 | OK |
| | oxide | | | imide | | | | | |
| Embodiment 2 | Ba titanate | 30 | 25 | Polyamide | 15 | 0.3 | 40 | 440 | OK |
| | | | | imide | | | | | |
| Embodiment 3 | Ba titanate | 80 | 60 | Polyamide | 48 | 0.8 | 70 | 550 | OK |
| | | | | imide | | | | | |
| Embodiment 4 | Ba/Sr | 50 | 30 | Polyamide | 22 | 0.8 | 150 | 140 | OK |
| | titanate | | | imide | | | | | |
| Embodiment 5 | Ba titanate | 40 | 40 | Polyvinylidene | 32 | 0.4 | 80 | 660 | OK |
| | | | | fluoride | | | | | |
| Embodiment 6 | Ba/Sr | 60 | 50 | Epoxy | 40 | 0.6 | 50 | 590 | OK |
| | titanate | | | | | | | | |
| Embodiment 7 | Ba titanate | 30 | 70 | Polyvinylidene | 65 | 0.7 | 70 | 820 | OK |
| | | | | fluoride | | | | | |
| Embodiment 8 | Ba titanate | 20 | 60 | Polyvinylidene | 58 | 0.4 | 50 | 1330 | OK |
| | | | | fluoride | | | | | |
| Comparative | Ba titanate | 600 | 60 | Epoxy | 60 | 20 | 3000 | 27 | OK |
| example 1 | | | | | | | | | |

Compared to conventional capacitor material using organic matrix, the present invention can realize high capacitance density simply by adding small amount of inorganic oxide to the material as explained in the embodiments above. Accordingly, the invention can bring about superior effects not only on the electrical characteristic as capacitor but also on other characteristics of insulation material for substrate including bondability and mechanical characteristic. Hence, reliability can improve drastically.

Since the organic/inorganic oxide compound film of the present invention comprises inorganic oxide particle and resin as described in the embodiments above, it can be integrated easily in a substrate without changing the existing production process of substrate, making it possible to form passive devices that function as decoupling capacitor, filter, and so on in the substrate. Accordingly, the number of passive devices that used to be mounted on the surface of a substrate can be reduced tremendously, thereby realizing high density packaging. The present invention contributes significantly to decrease the size and increase the performance of electronic appliances such as mobile phone.

Among the excellent characteristics of the compound film of the present invention and capacitor using the film, its low loss characteristic (tanδ is less than 1%) can be best utilized when it is used in high frequency appliances. In a high-speed module, for example, it can be used in combination with a common mode filter such as twist pair coil or magnetic material, making the best of its high capacitance (more than 1 nF/mm²). Sheet display can also make the best of this high capacitance, and so the present invention is suitable for memory capacitor, enabling to reduce the refresh cycles.

According to the present invention, a very thin compound film of inorganic oxide and organic polymer having very high capacitance density and excellent characteristic can be offered.

1. Organic/inorganic oxide mixed film made of practically spherical inorganic oxide particle, having a mean particle size of less than 90 nm, dispersed in organic polymer, of which relative dielectric constant is more than 10 and thickness is less than 900 nm.

2. Organic/inorganic oxide mixed film according to claim 1, wherein the thickness of the film is 300 to 800 nm.

3. Organic/inorganic oxide mixed film according to claim 1, wherein the organic polymer and oxide particle are contacted or coupled with each other directly or via coupling agent.

4. Organic/inorganic oxide mixed film according to claim 1, wherein unevenness of the thickness is less than 50 nm.

5. Organic/inorganic oxide mixed film according to claim 1, wherein the mean particle size of the inorganic oxide contained in the organic film is within a range from 10 to 80 nm.

6. Organic/inorganic oxide mixed film according to claim 1, wherein the volume percentage of the inorganic oxide contained in the organic film is 15 to 70 vol. %.

7. Organic/inorganic oxide mixed film according to claim 1, wherein the organic substance is fluorine containing polymer.

8. Organic/inorganic oxide mixed film according to claim 1, wherein the organic substance is epoxy compound.

9. Organic/inorganic oxide mixed film according to claim 1, wherein the inorganic oxide is barium titanate.

10. Organic/inorganic oxide mixed film according to claim 1, of which capacitance as capacitor is more than 1 nf/mm².

11. Organic/inorganic oxide mixed film according to claim 1, wherein the volume percentage of the inorganic oxide contained in the organic film is 20 to 50 vol. %.

12. A passive device contained electronic substrate self-containing a capacitor made of organic/inorganic oxide mixture, in which the relative dielectric constant of the composite film made of inorganic oxide, having a mean particle size of less than 90 nm, dispersed in organic polymer is more than 10 and thickness is less than 900 nm.

13. A passive device contained electronic substrate that has a capacitor which is made by placing the mixed film as set forth in any one of claims 1 to 11 between a pair of electrodes.

14. A passive device contained electronic substrate that self-contains a capacitor which is made by placing the mixed film as set forth in any one of claims 1 to 11 between a pair of electrodes.

15. A method of manufacturing organic/inorganic oxide mixed film, in which practically spherical inorganic oxide particle, having a mean particle size of less than 90 nm, is dispersed in organic solvent, the dispersed solution is mixed with organic polymer and dispersed in the organic polymer, and the mixture is then applied on the substrate surface of an electronic device board or electronic component and dried and/or hardened to form mixed film of which relative dielectric constant is more than 10 and thickness is less than 900 nm.

16. A method of manufacturing organic/inorganic oxide mixed film according to claim 15, wherein the inorganic oxide particle is prepared by a sol/gel method.

17. A method of manufacturing a passive device contained electronic substrate comprising:
laminating and bonding a laminated board for forming capacitor containing conductors between which is placed a capacitor made of organic/inorganic oxide mixture, in which the relative dielectric constant of the composite film made of inorganic oxide, having a mean particle size of less than 90 nm, dispersed in organic polymer is more than 10 and thickness is less than 900 nm, and a substrate containing an insulation layer and an inner conductor; and
forming required circuit patterns on an outer conductor layer.
